(19) United States
(12) Patent Application Publication
(10) Pub. No.: US 2026/0058109 A1
(43) Pub. Date: Feb. 26, 2026

(54) VERTICALLY MOUNTED PROCESSING SYSTEM

(71) Applicant: Tokyo Electron Limited, Tokyo (JP)

(72) Inventors: Matthew Charles Gwinn, Winchendon, MA (US); Jerry Negrotti, Beverly, MA (US); Paul Consoli, Ipswich, MA (US)

(21) Appl. No.: 19/253,017

(22) Filed: Jun. 27, 2025

Related U.S. Application Data
(60) Provisional application No. 63/687,232, filed on Aug. 26, 2024.

(51) Int. Cl. H01J 37/32

(52) U.S. Cl. CPC H01J 37/32743; H01J 37/3244; H01J 37/32715; H01J 2237/1503; H01J 2237/2007; H01J 2237/204

(57) ABSTRACT

A method for processing a wafer includes receiving the wafer on a flip assembly disposed in a processing chamber, the wafer being received in a first orientation parallel to a floor of the processing chamber, the flip assembly including a rotary bar coupled to a rotary drive. The method further includes transferring the wafer from the flip assembly to a wafer holder disposed in the processing chamber such that the wafer is disposed along a second orientation in the processing chamber, the second orientation being angled to the first orientation, and exposing the wafer in the second orientation to a flux of material.

### CROSS-REFERENCE TO RELATED APPLICATIONS

This application claims the benefit of U.S. Provisional Application No. 63/687,232, filed on August 26, 2024, which application is hereby incorporated herein by reference.

### TECHNICAL FIELD

The present invention relates generally to systems and methods for processing a wafer, and, in particular embodiments, to systems and methods for processing a wafer oriented vertically.

### BACKGROUND

Plasma etching is a widely employed process in the fabrication of integrated circuits (ICs), where selective areas of materials are removed from the surface of a semiconductor wafer using plasma-generated reactive species. These etch processes are used for shaping and patterning various layers during the complex steps involved in the fabrication of electronic devices.

While plasma etching offers several advantages, including high anisotropy and controllable etch rates, there are inherent challenges that industry practitioners encounter. One such challenge is the physical vibration of wafers caused by electromagnetic fields, pressure imbalances, or mechanical equipment connected to the etch chamber. These vibrations can adversely affect the feature resolution and uniformity of the etch process, impacting device performance and yield.

### SUMMARY

In accordance with an embodiment of this disclosure, a method for processing a wafer includes receiving the wafer on a flip assembly disposed in a processing chamber, the wafer being received in a first orientation parallel to a floor of the processing chamber, the flip assembly including a rotary bar coupled to a rotary drive. The method further includes transferring the wafer from the flip assembly to a wafer holder disposed in the processing chamber such that the wafer is disposed along a second orientation in the processing chamber, the second orientation being angled to the first orientation, and exposing the wafer in the second orientation to a flux of material.

In accordance with another embodiment of this disclosure, a system for processing a wafer includes a processing chamber including a processing tool, and a wafer holder oriented vertically, the processing tool including a processing nozzle. The system further includes a flip assembly disposed in the processing chamber, the flip assembly including a rotary bar, and a rotary drive, the rotary drive coupled to the rotary bar. And the system further includes a controller coupled to the wafer holder, the flip assembly, the processing chamber, the processing tool, and a memory storing instructions to be executed in the controller. The instructions when executed enable the controller to receive the wafer on the flip assembly, the wafer being received in a first orientation parallel to a floor of the processing chamber, transfer the wafer from the flip assembly to the wafer holder such that the wafer is disposed along a second orientation in the processing chamber, the second orientation being angled to the first orientation, and expose the wafer in the second orientation to a flux of material emitted from the processing nozzle of the processing tool.

And in accordance with yet another embodiment of this disclosure, a semiconductor processing platform includes one or more processing chambers configured to process one or more wafers oriented vertically using a flux of material emitted horizontally, and a wafer transfer chamber coupled to the one or more processing chambers. The wafer transfer chamber being configured to translate under vacuum one or more wafers oriented horizontally, rotate the one or more wafers oriented horizontally to be vertically oriented using a flip assembly, and load the one or more wafers oriented vertically into the one or more processing chambers for processing with the flux of material.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1A-1B are schematic diagrams of a vertically mounted processing system in accordance with an embodiment of this disclosure;

FIG. 2 is a schematic diagram of a flip assembly which may be used to load a wafer in a vertically mounted processing system in accordance with an embodiment of this disclosure;

FIGS. 3A-3C are top view schematic diagrams of the vertically mounted processing system illustrating various steps of a method for loading a wafer using the flip assembly of FIG. 2 in accordance with an embodiment of this disclosure;

FIG. 4 is a schematic diagram of a flip assembly which may be used to load a wafer in a vertically mounted processing system in accordance with an embodiment of this disclosure;

FIG. 5 is a front view schematic diagram of the vertically mounted processing system illustrating various steps of a method for loading a wafer using the flip assembly of FIG. 4 in accordance with an embodiment of this disclosure;

FIGS. 6A-6C are top view schematic diagrams of various tool layouts comprising vertically mounted processing systems in accordance with embodiments of this disclosure;

FIG. 7 is a top view schematic diagram of a tool layout comprising vertically mounted processing systems with maintenance doors in accordance with an embodiment of this disclosure; and

FIG. 8 is a flowchart of a method of processing a wafer in a vertically mounted processing system in accordance with an embodiment of this disclosure.

### DETAILED DESCRIPTION OF ILLUSTRATIVE EMBODIMENTS

Partial plasma etching (PPE) systems use a scanner (or wafer scanner) to scan a wafer beneath a plasma tool, which enables the processing of specific areas of the wafer exposed to a plasma emitted from the plasma tool. Typically, the scanner is mounted horizontally with the wafer and scanner disposed beneath the processing beam, jet, flux of material, or stream and processing tool. As a result, material removed from the wafer during processing may accumulate in the features being formed introducing potential defects. Another difficulty may result from the rapid motions of the scanner causing vibrations. The vibrations may cause defects during processing, and further, beats may occur from the interference patterns of multiple vibrations from multiple processing systems with scanners operating simultaneously, which may further negatively impact the precision and efficiency of the processing. Further, the horizontal orientation of the scanner and processing system occupies a large spatial footprint within a fabrication facility (taking up a large area of a cleanroom floor).

Existing approaches in the field attempt to address vibration control through passive or active damping mechanisms attached to etch processing equipment. However, these methods may not effectively reduce vibrations without compromising the efficacy of the plasma etch process nor significantly decrease the spatial footprint without limiting system capabilities.

Existing solutions for partial plasma etch applications often result in trade-offs between minimizing vibration and maintaining an effective etch process. Likewise, efforts to consolidate processing modules for footprint reduction can impact system accessibility, maintenance, and scalability.

This disclosure describes a vertically mounted processing system and a flip assembly and loading method which may be used to load a wafer in a vertically mounted processing system. The system, flip assembly, and method of this disclosure address both vibration mitigation during partial plasma etch processes and reduction of the processing module's physical footprint without sacrificing performance, efficiency, or overall system functionality. By mounting the processing system with a scanner vertically, forces and energy from rapid acceleration and movement of the scanner may be directed along the vertical mounted direction and dissipated through mounts to a cleanroom floor, which significantly reduces vibrations and prevents vibrations from negatively impacting feature formation during processing.

Further, processing modules comprising vertically mounted processing systems in accordance with embodiments of this disclosure have a smaller physical footprint, thus occupying less surface area of the cleanroom floor. And processing modules comprising vertically mounted processing systems in accordance with embodiments of this disclosure also significantly dampen beats which may form from the interference of the vibrations of multiple scanners operating simultaneously. Additionally, by vertically mounting processing systems, the material removed from the wafer during processing may fall to a floor of the processing chamber without accumulating in features or on other elements of the processing system. As a result, maintenance or cleaning steps may be reduced, which may increase throughput and the efficiency of the processing system and processing module comprising vertically mounted processing systems.

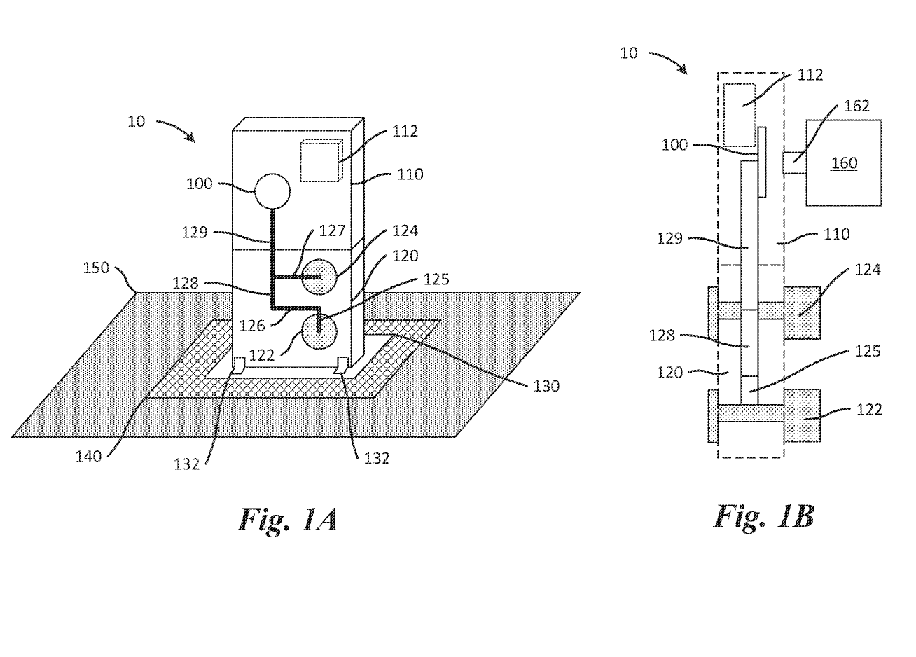

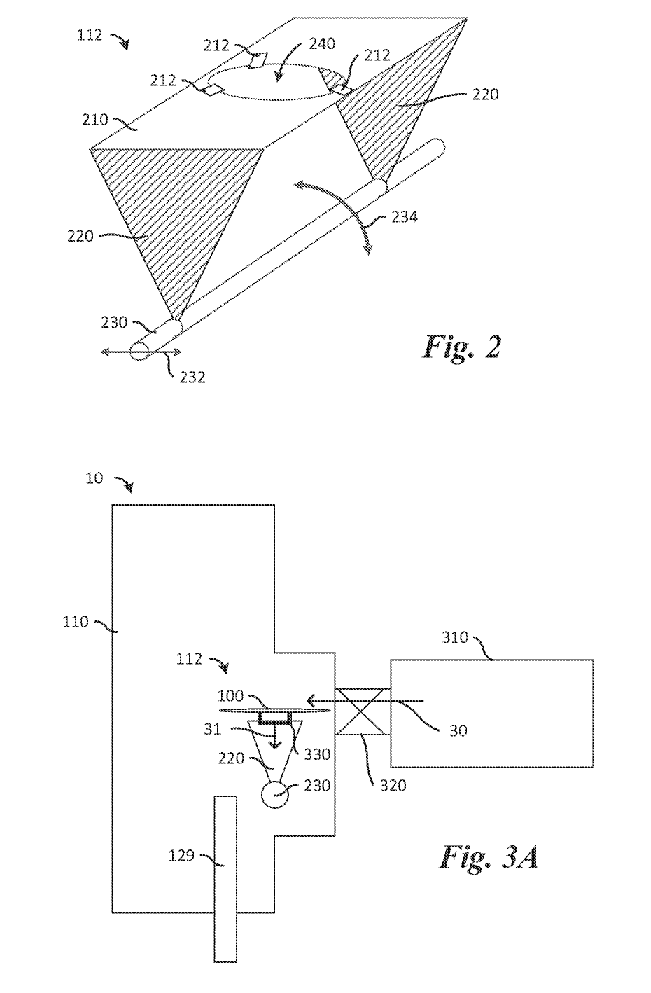

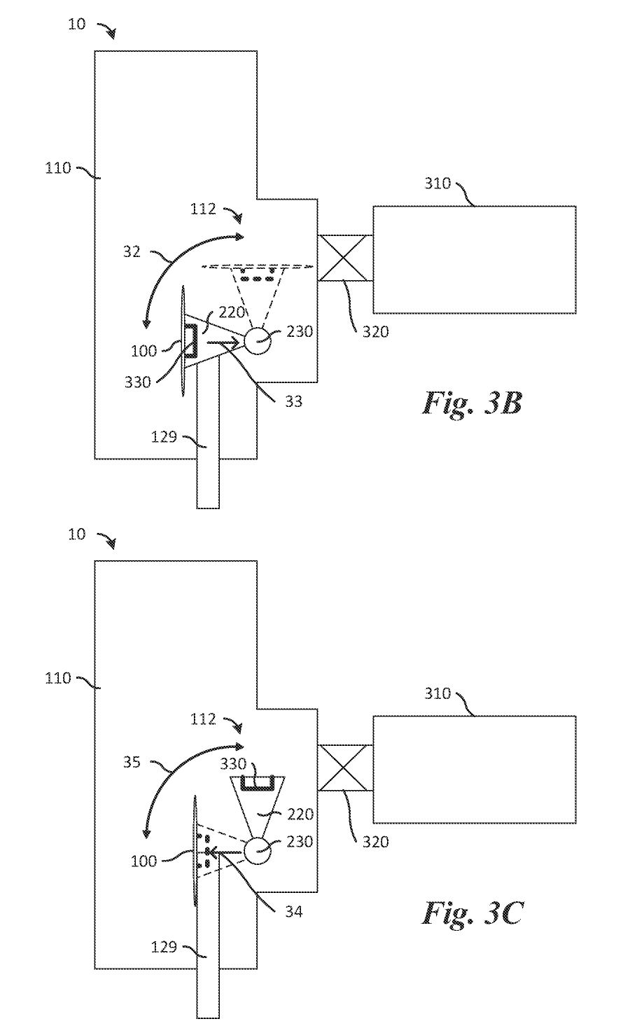

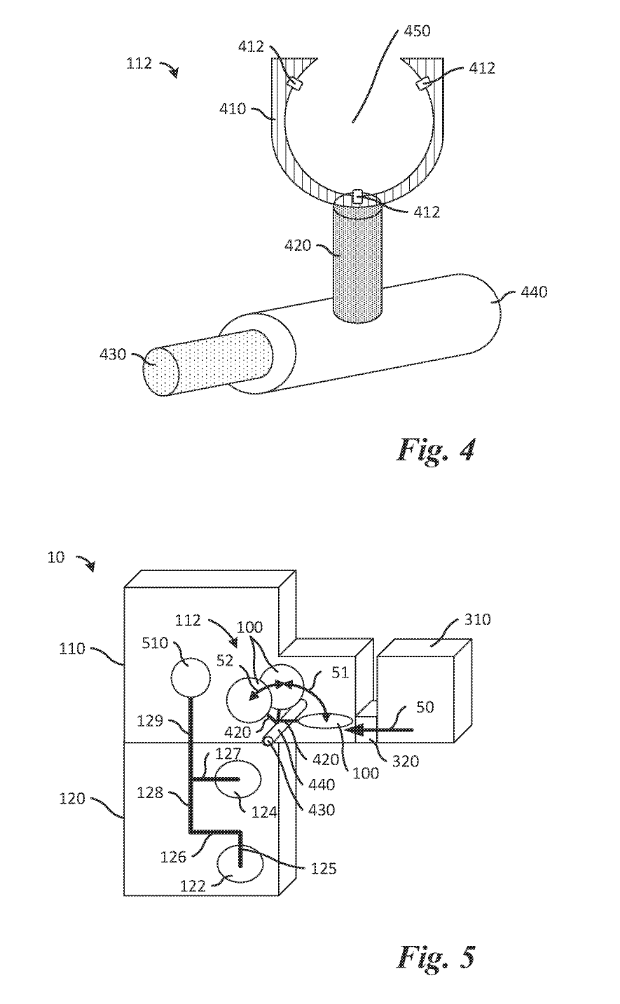

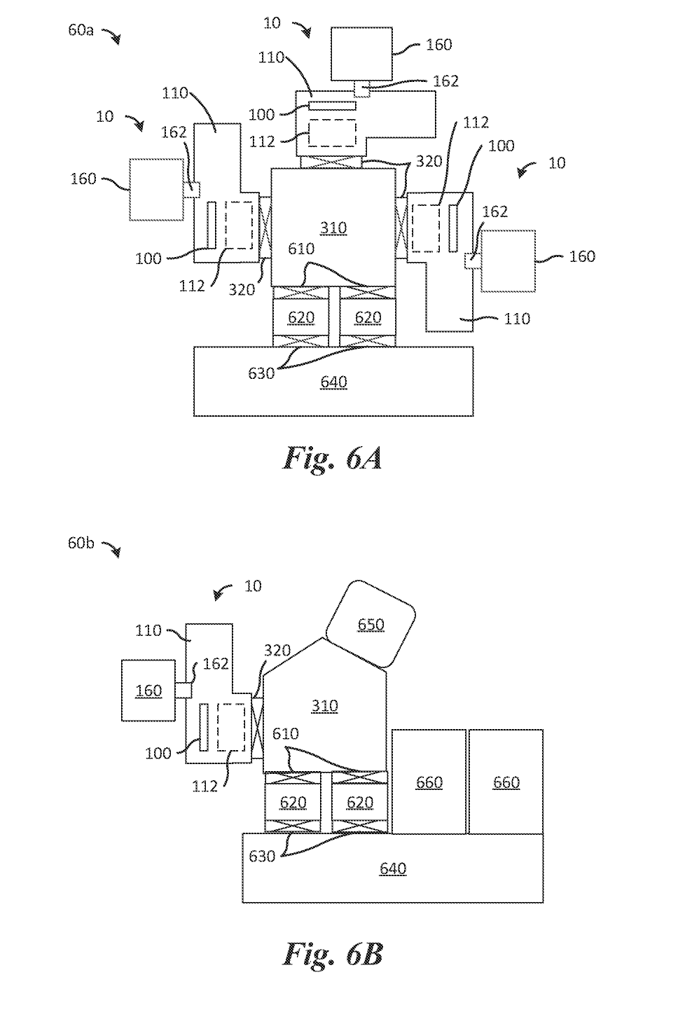

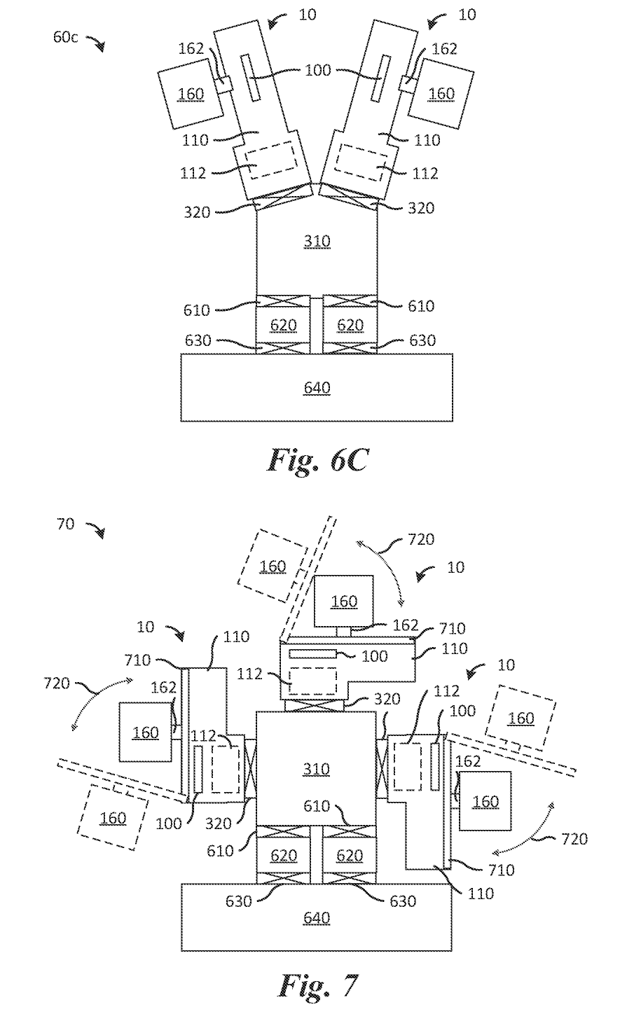

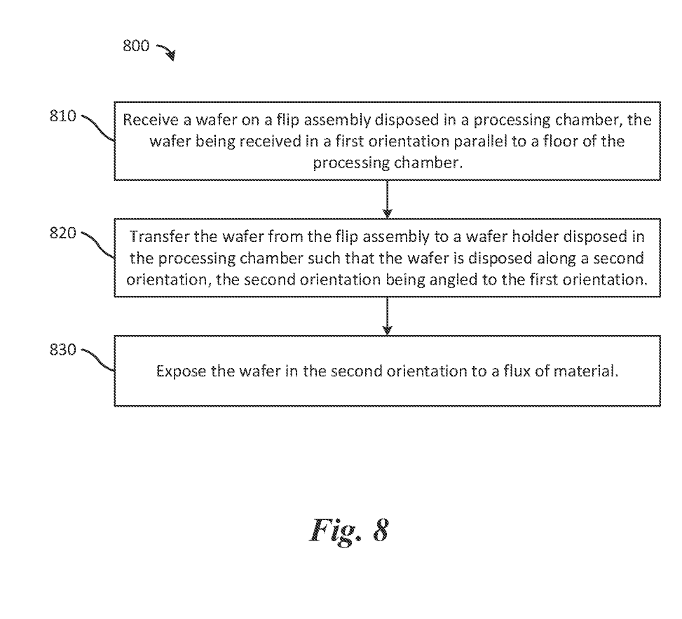

Embodiments provided below describe various methods, apparatuses, and systems for processing a wafer, and in particular, to methods, apparatuses, and systems that may prevent vibrations during the processing of a wafer by vertically mounting a processing system. The following description describes the embodiments. FIGS. 1A-1B are used to describe an example vertically mounted processing system. FIG. 2 is used to describe an example flip assembly which may be used to load a wafer from a wafer transfer chamber into a wafer holder of a scanner of the vertically mounted processing system. An example method of loading the wafer into the wafer holder of the vertically mounted processing system using the flip assembly of FIG. 2 is described using FIGS. 3A-3C. Another example flip assembly is described using FIG. 4. FIG. 5 is used to describe an example method of loading the wafer into the wafer holder of the vertically mounted processing system using the flip assembly of FIG. 4. FIGS. 6A-6C are used to describe various example embodiments of processing modules comprising vertically mounted processing systems of this disclosure. An example processing module comprising vertically mounted processing systems with maintenance doors is described using FIG. 7. And FIG. 8 is used to describe another example method of loading a wafer into a wafer holder of a vertically mounted processing system of this disclosure.

FIGS. 1A-1B are schematic diagrams of a vertically mounted processing system 10 in accordance with an embodiment of this disclosure. As a result of the vertically mounted processing system 10 being mounted vertically, vibrations resulting from the rapid movements and accelerations during the scanning of a wafer 100 may be prevented. Further, in embodiments comprising multiple processing systems, mounting the processing systems vertically prevents beats occurring from the interference of the vibrations from the multiple processing systems.

FIG. 1A is a front view schematic diagram of the vertically mounted processing system 10 in accordance with an embodiment of this disclosure. The vertically mounted processing system 10 comprises a wafer 100 disposed in a processing chamber 110, and a scanning chamber 120. In various embodiments, the vertically mounted processing system 10 may be an element of a processing module, where the processing module comprises additional elements such as a wafer transfer system, a heater, a gate valve, a load-lock, and etcetera. As illustrated in FIG. 1A, the vertically mounted processing system 10 may be mounted to a pedestal 130 via module mounts 132, where a module base 140 (the footprint of a processing module comprising the vertically mounted processing system 10) surrounds the pedestal 130 of a cleanroom floor 150.

In various embodiments, the wafer 100 may be any conventional wafer desired to be processed using the vertically mounted processing system 10 of this disclosure. For example, the wafer 100 is a silicon wafer in one embodiment. In some embodiments, the wafer 100 is a semiconductor substrate, such as a silicon substrate comprising various dielectric layers desired to be processed using the vertically mounted processing system 10. In other embodiments, the wafer 100 may be other semiconductors substrates including silicon-on-insulator substrates, silicon carbide, gallium arsenide More possible wafers include flat panel displays, photolithography masks, and others. Although many wafers are circular, there is no specification that the wafer 100 be circular or even substantially circular. For example, the wafer 100 may be circular, square, rectangular, or any other desired shape including irregular shapes.

The processing chamber 110 may be any suitable processing chamber for processing the wafer 100. Further, the processing chamber 110 comprises the wafer 100, and a flip assembly 112 which may be used to load the wafer 100 into a wafer holder of a scanner. The flip assembly 112 enables the vertical mounting of the processing system by receiving the wafer 100 in a horizontal orientation, flipping the wafer 100 into a vertical orientation, and subsequently loading the wafer 100 in a wafer holder of the vertically mounted processing system 10 vertically and without dropping the wafer 100 within the processing chamber 110. Additionally, the processing chamber 110 may be coupled to a processing tool (such as illustrated in FIG. 1B). In various embodiments, the processing chamber 110 may be a vacuum chamber configured for dry etching the wafer 100 using a plasma, such as a partial plasma etching (PPE) chamber. In other embodiments, the processing chamber 110 may be a gas cluster chamber.

The scanning chamber 120 may be mechanically coupled to the processing chamber 110 through a feedthrough to enable a scanning arm 129 of a scanner to move the wafer 100 around the processing chamber 110 during processing. As illustrated in FIG. 1A, the scanning chamber 120 comprises a scanner or scanning mechanism comprising actuators, moving parts, hinges, and a wafer holder, collectively referred to as a wafer scanner.

In various embodiments, the scanning chamber 120 further comprises a controller (not shown) to control a first rotary drive 122, and a second rotary drive 124 of the wafer scanner as will be described in more detail below. One advantage of having separate scanning and processing chambers is that it helps protect moving parts of the wafer scanner from contaminants originating in the processing chamber 110. Additionally, the vertical orientation of the vertically mounted processing system 10 enables material removed from the wafer 100 during processing to fall from the wafer 100 without additional (or intermediate) cleaning steps to remove residue. In one embodiment, controlled pressure difference between the scanning chamber 120 and the processing chamber 110 may be maintained to prevent byproducts produced inside the processing chamber 110 during processing from entering the scanning chamber 120 and depositing on the parts of the wafer scanner.

In one embodiment, two rotary drives (the first rotary drive 122 and the second rotary drive 124) are used as the primary actuators of the wafer scanner. One advantage of using rotary drives is cleanliness, hence lower maintenance cost because, unlike linear bearings, rotary bearings may be sealed from contaminants in the ambient. Synchronous angular displacements of the first and the second rotary drives 122 and 124 may be accurately computed in accordance with a desired planar trajectory of the center of the wafer holder, and subsequently used by a controller (not shown) to generate the computed synchronized rotational motions with high precision for scanning the wafer 100 beneath a processing beam, jet, flux of material, or stream from a processing tool of the vertically mounted processing system 10. Control of backlash in the mechanical design of rotary parts may be implemented for precise positioning of the wafer 100. Generally, the choices of drives, couplings and bearings are made to reduce backlash.

The synchronized pair of rotations actuated by the first and the second rotary drives 122 and 124 is converted to a target scan trajectory of the center of the wafer holder via various other moving parts of the wafer scanner. The trajectory of the wafer holder, hence, also the trajectory of the wafer 100 loaded vertically onto the wafer holder (using the flip assembly 112), is substantially coplanar with (or parallel to) the processing surface of the wafer 100. In various embodiments, the wafer holder of the wafer scanner may be any suitable wafer holder known in the art, such as an electrostatic chuck (ESC) which holds the wafer 100 to the wafer holder on the scanning arm 129 during processing using an electrostatic force. In other embodiments, the wafer holder may be a vacuum chuck, a mechanical clamp, a magnetic chuck, or etcetera.

In one embodiment, the rotational motion of the first and the second rotary drives 122 and 124 may be translated to a planar motion along the plane of the surface of wafer 100 using a bar-and-hinge system as the wafer scanner. The bar-and-hinge system (or wafer scanner) comprises five bar links (a first bar link 127, a second bar link 128, a third bar link 125, a fourth bar link 126, and a belted fifth bar link (which may be referred to as the scanning arm 129)), and three hinges about which the bar links may rotate.

In various embodiments, the belted fifth bar link (or scanning arm 129) comprises a bar link and a motorized belt-and-pulley system in the bar link. The motorized belt-and-pulley system may be used to orient the wafer 100 by rotating the planar surface of the wafer holder along with the wafer 100. In various other embodiments, the mechanism used to rotate the wafer holder may be implemented differently.

As illustrated in FIG. 1A, the first and the second rotary drives 122 and 124 are affixed to the body of the scanning chamber 120. Each rotary drive rotates one end of a respective bar link directly connected to the drive. In FIG. 1A, the fourth bar link 126 is attached to the first rotary drive 122 and, at the opposite end, to a free moving first hinge. The first bar link 127, attached to the second rotary drive 124, has its opposite end connected to another free moving third hinge. The pair of synchronized rotations of the actuated first and fourth bar links 127 and 126 (synchronized by the controller, as described above) causes a respective synchronized pair of displacements of the first and the third hinges. The first and the third hinges transmit the motion to other bar links attached to the first and the third hinges.

The first hinge is attached to one end of the third bar link 125, and the third hinge is attached to one end of the second bar link 128. The opposite ends of the second and the third bar links 128 and 125 are both connected to the second hinge. This causes a motion of the second hinge conforming to the trigonometric relations between the angles of a triangle having two sides determined by the lengths of two bar links (second and third bar links 128 and 125) and the third side being the line segment connecting the first and the third hinges. The distance between the first and the third hinges may be determined by a combination of their synchronized displacements described above. In one embodiment, the repositioning of the second hinge determines the trajectory of the center of the wafer holder (and of the wafer 100).

One end of the belted fifth bar link (scanning arm 129) may be attached to the wafer holder and the opposite end may be attached to the third hinge and the second bar link 128. The connection between the second bar link 128 and the belted fifth bar link (scanning arm 129) allows the two-bar combination to pivot around the third hinge while the angle formed by the two bars is held fixed. Accordingly, in this embodiment of the wafer scanner, the location of the center of the wafer holder is uniquely determined by the combined positions of second and third hinges and the combined lengths of the second bar link 128 and the belted fifth bar link (scanning arm 129).

All elements of the wafer scanner may be used to scan the wafer 100 such that the entire surface of the wafer 100 may be exposed to a processing beam, jet, flux of material, or stream from the processing tool of the processing chamber 110. For example, in some embodiments, a raster-pattern may be traced over the surface of the wafer 100 using the various movements the wafer scanner. As mentioned above, the wafer 100 is processed by scanning its surface through a stationary processing beam, jet, flux of material, or stream (e.g., a stationary beam comprising gas clusters). In the embodiments described in this disclosure, the scan trajectory of any point on the wafer surface is coplanar with the roughly planar surface of the wafer 100, or equivalently, the scanning plane and the processing plane are coincident and are vertical. One advantage of using scanning apparatus where the scanning plane is roughly same as the processing plane is that the distance between the beam source and the beam spot (the spot where the wafer intersects the processing beam, jet, flux of material, or stream) is roughly constant throughout the scan. This is advantageous in keeping the processing beam, jet, flux of material, or stream focused on the wafer 100 during the entire wafer scan, thereby improving control over the size and shape of the beam spot.

As illustrated in FIG. 1A, in one embodiment, the wafer 100 is placed on the wafer holder of the scanning arm 129 such that the centers of the wafer holder and wafer 100 are substantially coincident. The wafer 100 may be rotated into a vertical orientation after being received from a wafer transfer chamber in a horizontal orientation. The loading of the wafer 100 into the wafer holder of the scanning arm 129 may be accomplished using the flip assembly 112. Various embodiments of the flip assembly 112 may be as described using FIG. 2 and FIG. 4 below.

The cleanroom floor 150 is a meticulously designed flooring system crafted to meet the rigorous cleanliness standards desired in semiconductor fabrication and other contamination-sensitive industries. Constructed from high-density, chemically-resistant materials like vinyl or epoxy, the cleanroom floor 150 provides a seamless, non-porous surface that minimizes particle accumulation and facilitates easy cleaning. In various embodiments, the cleanroom floor 150 is installed over a network of stainless steel or aluminum raised floor panels, which are precisely leveled to create a uniformly smooth surface that supports the filtration and airflow systems used to maintain a controlled cleanroom environment. The cleanroom floor 150 may comprise isolated mounting systems for processing modules which minimize vibrations during fabrication steps, such as the pedestal 130.

The pedestal 130 is a precision-engineered support structure designed specifically for mounting equipment on the cleanroom floor 150, providing stability and vibration isolation essential for high-precision operations. In various embodiments, the pedestal may be constructed from stainless steel to ensure durability, corrosion resistance, and ease of sanitation. Further, the pedestal 130 may have a robust square or rectangular base that evenly distributes the equipment load and integrates seamlessly with the raised floor system of the cleanroom. The module base 140 of the processing module comprising the vertically mounted processing system 10 of FIG. 1A may be affixed to the pedestal 130 using the module mounts 132.

The module mounts 132 are specialized interface components designed for securely affixing and vertically mounting a processing system to the pedestal 130 situated on the cleanroom floor 150 to mount the vertically mounted processing system 10, ensuring both stability and precision alignment desired for optimal performance. In various embodiments, each module mount 132 may be constructed from high-strength stainless steel or anodized aluminum, offering durability and resistance to cleanroom chemicals while minimizing the risk of contamination. The base of each module mount 132 may comprise pre-drilled, countersunk holes designed for efficient fastening to the pedestal 130, providing a stable foundation and mount to orient the vertically mounted processing system 10. In some embodiments, further integrated into the base of the module mount are vibration-dampening gaskets made from high-performance elastomeric materials such as neoprene or silicone, which effectively absorb mechanical shocks and vibrations, maintaining the integrity of delicate processing operations.

The vertically mounted processing system 10 has several benefits over conventional systems mounted horizontally. One benefit of vertically mounting a processing system in accordance with embodiments of this disclosure is that forces resulting from the rapid movements of the wafer scanner during processing may be directed along the vertical direction into the pedestal 130 of the cleanroom floor 150. As a result, the forces are directed such that vibrations are further minimized and dissipated through the module mounts 132 without negatively influencing the processing of the wafer 100. And beats which may occur from the simultaneous processing using multiple processing systems may be averted, which is an additional benefit. Another benefit of vertically mounting the processing system in accordance with embodiments of this disclosure is that the module profile (spatial footprint) of the vertically mounted processing system 10 is minimized. In other words, the surface area of the cleanroom floor 150 the vertically mounted processing system 10 occupies is smaller than conventional horizontally mounted processing systems. A side view of the vertically mounted processing system 10 may be described using FIG. 1B.

FIG. 1B is a side view schematic diagram of the vertically mounted processing system 10 of FIG. 1A in accordance with an embodiment of this disclosure. The vertically mounted processing system 10 of FIG. 1B comprises the wafer 100 disposed on the scanning arm 129 of the scanner in the processing chamber 110, the scanning chamber 120, and a processing tool 160 configured to emit a material for processing the wafer 100 through a processing nozzle 162 into the processing chamber 110. Similarly labeled elements may be as previously described. In contrast to FIG. 1A, the flip assembly 112 of the vertically mounted processing system 10 of FIG. 1B is disposed behind the scanning arm 129 to load the wafer 100.

Processing tool 160 may comprise a location-specific processing tool capable of emitting a flux of material to controllably process a portion of a top surface of the wafer 100 relative to another location. For example, one location of the wafer 100 can be treated while minimally processing another location of the wafer 100. The flux of material may be emitted in the form of a processing beam, jet, flux of material, or stream. The processing tool 160 may be coupled to processing chamber 110, wherein relative motion can be created between the wafer 100 and the processing tool 160. In one embodiment, relative motion is generated by scanning wafer 100 through the processing beam, jet, flux of material, or stream using a scanner to translate wafer 100. Further, e.g., wafer 100 can be translated in a vertical plane while the flux of material is emitted in a direction orthogonal to the wafer 100 or vertical plane, i.e., wafer 100 is oriented vertically and processing beam, jet, flux of material, or stream is directed in a substantially horizontal direction. However, in some embodiments, the scanner may be capable of tilting the wafer 100 relative to the emitted flux of material. Further, e.g., the processing tool 160 can be configured to emit the flux of material along a direction inclined relative to horizontal.

In various embodiments, the flux of material may be in the gas-phase. In one or more embodiments, the flux of material may be emitted in the form of a beam, jet, or stream. For example, the flux of material may comprise an uncharged particle, a charged particle, a neutral species, a radical, a metastable species, a gas cluster, or an ion. Additionally, the flux of material may comprise plasma effluents that may or may not contain charged species. As another example, the flux of material may comprise radicals generated upstream and emitted by the processing tool 160. In one or more embodiments, the flux of material emitted by the processing tool 160 may comprise gas clusters, ions, radicals, neutral species, or combinations thereof.

The processing tool 160 may be any suitable processing tool for the desired processing of the wafer 100. For example, the processing tool 100 may be a partial plasma etching (PPE) tool configured to emit a plasma beam into the processing chamber 110 through the processing nozzle 162 and onto the wafer 100 in an embodiment. In other embodiments, the processing tool 160 may be a gas cluster tool configured to emit a beam comprising gas clusters through the processing nozzle 162 into the processing chamber 110 and onto the wafer 100. In other embodiments, the processing tool 160 may be a tool configured to emit a processing beam, jet, flux of material, or stream through the processing nozzle 162 into the processing chamber 110. In some embodiments, the processing tool 160 may be used to deposit material over the wafer 100. And the processing nozzle 162 may be conventional processing nozzles known in the art for the corresponding processing tool 160 of the vertically mounted processing system 10.

In one or more embodiments, the processing tool 160 may be configured to emit the flux of material over the entire top surface of the wafer 100, where the wafer 100 and the processing tool 160 remain stationary during processing. In other embodiments, the processing tool 160 may be configured to emit the flux of material over a localized spot (or portion) of a top surface of the wafer 100, where a relative motion between the wafer 100 and the processing tool 160 is formed using a scanner to enable portions of the top surface of the wafer 100 to be processed as desired.

The flip assembly 112 enables processing of the vertically mounted wafer 100 by providing the ability to load the wafer 100 into the wafer holder of the scanner. Conventional wafer transfer chambers provide the wafer oriented with the surface of the wafer parallel with the surface of the cleanroom floor (or horizontally). As a result, before the wafer 100 is processed, the wafer 100 is flipped into a vertical orientation and loaded into the wafer holder of the scanner using the flip assembly 112. An embodiment flip assembly 112 which may enable the loading and subsequent processing of the wafer 100 in the vertically mounted processing system 10 of FIGS. 1A-1B is described using FIG. 2 below.

FIG. 2 is a schematic diagram of a flip assembly 112 which may be used to load a wafer 100 in a vertically mounted processing system in accordance with an embodiment of this disclosure. For example, the flip assembly 112 of FIG. 2 may be used to load the wafer 100 in the vertically mounted processing system 10 of FIGS. 1A-1B. The flip assembly 112 comprises a wafer holder 210 coupled to a shaft 230 via supports 220. The wafer holder 210 comprises a hole 240 and edge clamps 212 which may be used to hold the wafer over the hole 240.

In various embodiments, the wafer holder 210 may be any suitable material for holding a wafer during the method of loading a wafer in a vertically mounted processing system of this disclosure. For example, the wafer holder 210 may be a piece of machined metal comprising the hole 240 and edge clamps 212 disposed around the hole 240. In various embodiments, the hole 240 may be large enough to allow the wafer to pass through, and may be any suitable shape for the shape of the wafer to be loaded into a vertically mounted processing system of this disclosure. The hole 240 may be circular, rectangular, square, ovular, or any other suitable shape that allows the wafer to pass through during the loading according to the method of loading a wafer using the flip assembly 112 of this disclosure.

The edge clamps 212 may be any suitable clamping mechanism known in the art, and may be any suitable number of clamps for holding the wafer over the hole 240 of the flip assembly 112 during the loading. In various embodiments, three edge clamps 212 may be used, but other embodiments may use as many as four, or five edge clamps.

The supports may be of any material known in the art suitable for holding the wafer holder 210. In various embodiments, the supports 220 may be of the same material as the wafer holder 210 described above. Further, the shape of the supports 220 may be any suitable shape for mechanically coupling the wafer holder 210 to the shaft 230 and leaving an offset (or gap) between them to enable the scanning arm 129 of the wafer scanner to pass between. As a result of maintaining an offset between the wafer holder 210 and the shaft 230, the flip assembly 112 may flip over the scanning arm 129 to position the wafer 100 vertically in alignment with the wafer holder of the scanning arm 129 to enable loading the wafer 100 into the wafer scanner for processing.

The shaft 230 may be any material suitable for attaching to the supports 220. For example, the material of the shaft may be the same as the material for the wafer holder 210 and the supports 220. In various embodiments, the shaft 230 may be a rotary arm. The shaft 230 may be attached to a rotary drive (not shown) and a bellows (not shown). In various embodiments, the shaft 230 may be rotated to perform rotations to flip the wafer 100 over the scanning arm 129 of the wafer scanner. For example, the shaft 230 may be capable of rotation 234, which may flip the wafer 100 from a horizontal orientation into a vertical orientation. As another example, the bellows (not shown) may enable the shaft 230 to perform translational movements to ensure the wafer 100 is properly aligned over the scanning arm 129 before releasing edge clamps 212 to load the wafer 100 in the scanning arm 129 vertically. In some embodiments, the shaft 230 may be capable of translation movement 232.

In other embodiments, the flip assembly 112 may further comprise a pedestal (not shown) which may be oriented beneath the hole 240 and capable of moving up and down through the hole 240. The pedestal may be used to receive the horizontally oriented wafer 100 from a wafer transfer chamber, and then lower through the hole 240 to position the wafer 100 suitably for clamping with the edge clamps 212. The pedestal (not shown) may be as illustrated and described for pedestal 330 in FIGS. 3A-3C. Further, the flip assembly 112 illustrated in FIG. 2 may further comprise a controller (not shown) coupled to a memory (not shown) storing instructions for loading the wafer into a wafer holder of the vertically mounted processing system in accordance with embodiments of this disclosure. And the controller and memory may be any suitable device known in the art for storing and implementing the instructions for flipping the wafer into a vertical orientation and subsequently loading the wafer in the vertically mounted processing system. Various steps of an embodiment method for loading the wafer into a vertically oriented scanner of a vertically mounted processing system may be described using FIGS. 3A-3C below.

FIGS. 3A-3C are top view schematic diagrams of the vertically mounted processing system 10 illustrating various steps of a method for loading a wafer 100 using the flip assembly 112 of FIG. 2 in accordance with an embodiment of this disclosure. Similarly labeled elements may be as previously described.

FIG. 3A is a top view schematic diagram of the vertically mounted processing system 10 illustrating a transferring 30 of the wafer 100, and a lowering 31 of the wafer 100 onto a pedestal 330 in accordance with a method for loading a wafer in a vertically mounted processing system 10 using the flip assembly 112 of FIG. 2. During the transferring 30, the wafer 100 may be transported from a wafer transfer chamber 310 through a gate valve 320 (or load lock) and into the pedestal 330 of the flip assembly 112 using, for example, an (r, θ, z) robotic arm disposed in the wafer transfer chamber 310.

Once the wafer 100 is loaded in the pedestal 330, the lowering 31 lowers the pedestal 330 through the hole 240 of the wafer holder 210 until the wafer 100 is positioned as desired over the hole 240. And once the pedestal 330 has lowered the wafer 100 to the desired position in the lowering 31, edge clamps 212 may be used to clamp and affix the wafer 100 in the flip assembly 112.

In various embodiments, the wafer transfer chamber 310 is a precisely engineered enclosure designed to facilitate the seamless transfer of wafers between various processing environments while maintaining strict contamination control standards. The wafer transfer chamber 310 may be constructed from anodized aluminum for its lightweight and corrosion-resistant properties, where the chamber features an airtight seal system comprising O-rings and gaskets to ensure a vacuum-tight operation. The interior of the chamber may be equipped with a wafer handling robot, which includes a multi-axis robotic arm optimized for delicate wafer handling. The robot may be capable of precise, repeatable movements programmed via the chamber's control system to accurately align and transfer wafers between the wafer transfer chamber 310 and adjoining processing chambers 110 through gate valve 320.

The gate valve 320, positioned between the wafer transfer chamber 310 and the processing chamber 110, accommodates precise control over the isolation and transfer of wafers (such as wafer 100). In various embodiments, the gate valve 320 comprises a robust rectangular frame fabricated from stainless steel to ensure structural integrity and durability under high-vacuum conditions. In some embodiments, integrated within the frame may be a valve plate, which is capable of horizontal translational movement, actuated by a pneumatic cylinder. The valve plate may be lined with an elastomeric seal that ensures an airtight closure when the gate valve 320 is in the closed position. The pedestal 330 may be a conventional device known in the art for receiving and loading the wafer 100 onto the wafer holder 210 of the flip assembly 112 through the hole 240.

FIG. 3B is a top view schematic diagram of the vertically mounted processing system 10 illustrating a rotating 32 of the wafer 100 in the flip assembly 112, and a loading 33 of the wafer 100 onto a wafer holder of the scanning arm 129 in accordance with a method for loading a wafer in a vertically mounted processing system 10 using the flip assembly 112 of FIG. 2.

After the lowering 31 of the pedestal 330 to load the wafer 100 in the wafer holder 210 of the flip assembly 112, the method of loading the wafer in a vertically mounted processing system may then rotate the flip assembly 112 in the rotating 32. In the rotating 32, the flip assembly 112 may use a rotary drive to rotate the shaft 230 such that the wafer holder 210 is vertical and the scanning arm 129 passes through the offset between the wafer holder 210 and the shaft 230 created by the supports 220. And once the wafer 100 is vertically oriented and aligned with the scanning arm 129, the method may then perform the loading 33, which moves the flip assembly 112 to the wafer holder of the scanning arm 129 through a translational movement (such as the translational movement 232 illustrated in FIG. 2). The wafer 100 is then transferred, or loaded into the wafer holder of the scanning arm 129 of the wafer scanner after ensuring the alignment and positioning is correct such that the wafer 100 is not dropped within the processing chamber 110.

In various embodiments, the wafer holder 210 may further comprise capacitive sensors which may enable the flip assembly 112 to release the edge clamps 212 holding the wafer 100 into the wafer holder of the scanning arm 129 once proximity is detected and after the wafer holder of the scanning arm 129 has been verified as ready to hold the wafer 100 (such as by powering on). For example, in an embodiment where the wafer holder of the scanning arm 129 is an electrostatic chuck (ESC), the flip assembly 112 may detect proximity and alignment using sensors of the wafer holder 210, and then release the edge clamps 212 holding the wafer 100 after verifying the ESC is powered on and ready to receive the wafer 100 using an electrostatic force from the ESC.

FIG. 3C is a top view schematic diagram of the vertically mounted processing system 10 illustrating an offsetting 34 of the flip assembly 112 from the scanning arm 129, and a rotating 35 of the flip assembly 112 away from the scanning arm 129 in accordance with a method for loading a wafer in a vertically mounted processing system 10 using the flip assembly 112 of FIG. 2. In various embodiments, the offsetting 34 moves the flip assembly 112 away from the wafer holder of the scanning arm 129 after loading the wafer 100. And after the offsetting 34, the flip assembly 112 is moved from between the processing tool of the processing chamber 110 and the scanning arm 129 by the rotating 35. The rotating 35 may be performed by using a driver to rotate the shaft 230.

Once the flip assembly 112 has completed the loading of the wafer 100 in the wafer holder of the scanning arm 129 and has moved away from the processing tool of the processing chamber 110, the wafer 100 may be processed using the processing tool. For example, the processing tool may then be used to emit a beam, jet, or stream to etch material from the wafer 100 while the wafer 100 is scanned using the wafer scanner of the scanning chamber 120 in a raster pattern.

Other embodiments of the flip assembly 112 may be used to enable the vertical mounting of the processing system in accordance with embodiments of this disclosure. Another embodiment flip assembly 112 is described using FIG. 4 below.

FIG. 4 is a schematic diagram of a flip assembly 112 which may be used to load a wafer 100 in a vertically mounted processing system in accordance with an embodiment of this disclosure. For example, the flip assembly 112 of FIG. 4 may be used to load the wafer 100 in the vertically mounted processing system 10 of FIGS. 1A-1B. In contrast to the embodiment flip assembly 112 illustrated in FIG. 2, the flip assembly 112 of FIG. 4 rotates the wafer 100 about two axes during the loading, which enables the flip assembly 112 to be disposed on a sidewall of the processing chamber 110 proximal the scanning arm 129.

Referring to the flip assembly 112 of FIG. 4, the flip assembly 112 comprises a u-shaped wafer holder 410, a first rotary bar 420, a second rotary bar 430, and an assembly sheath 440. The u-shaped wafer holder 410 comprises a hole 450 and edge clamps 412, where the edge clamps 412 may be used to clamp the edges of a wafer to hold the wafer in the flip assembly 112 disposed over the hole 450. The hole 450 may be as previously described for the hole 240 of the flip assembly 112 of FIG. 2. The edge clamps 412 may also be as previously described for the edge clamps 212 of the flip assembly of FIG. 2.

The first rotary bar 420 may enable the rotation of the u-shaped wafer holder 410 about a primary axis along the first rotary bar 420. The first rotary bar 420 may be mechanically coupled to the second rotary bar 430 through conventional methods known in the art that enable the rotation of the first rotary bar 420 as the second rotary bar 430 is rotated. Thus, as the second rotary bar 430 is rotated, the first rotary bar also rotates, and the combinations of the rotations flip the wafer 100 from a horizontal orientation into a vertical orientation for loading in the vertically mounted processing system 10 of this disclosure.

Still referring to FIG. 4, the assembly sheath 440 may house the coupling mechanism between the first rotary bar 420 and the second rotary bar 430, and may facilitate translational movement of the flip assembly 112 through a bellows. In various embodiments, the second rotary bar 430 is coupled to a rotary drive to control the rotations of the second and first rotary bars 430 and 420. A method of using the flip assembly 112 of FIG. 4 to load a wafer 100 in a wafer holder 510 of the wafer scanner of the vertically mounted processing system 10 of this disclosure is described using FIG. 5 below.

FIG. 5 is a front view schematic diagram of the vertically mounted processing system 10 illustrating various steps of a method for loading a wafer 100 using the flip assembly 112 of FIG. 4 in accordance with an embodiment of this disclosure. Further, FIG. 5 illustrates a transferring 50 of the wafer 100 into the flip assembly 112, a first rotation 51 of the wafer 100 using the flip assembly 112, and a second rotation 52 of the wafer 100 using the flip assembly 112 in accordance with a method of loading a wafer into the vertically mounted processing system 10 using the flip assembly 112 of FIG. 4.

The method of loading the wafer 100 into a wafer holder 510 of the vertically mounted processing system 10 may begin with the transferring 50 of the wafer 100 into the flip assembly 112. The wafer 100 may be sent through the gate valve 320 from the wafer transfer chamber 310 during the transferring 50, such as using an (r, θ, z) robotic arm disposed in the wafer transfer chamber 310. The transferring 50 may load the wafer 100 in the u-shaped wafer holder 410 of the flip assembly 112.

After receiving the wafer 100 in the u-shaped wafer holder 410 of the flip assembly 112, the method may proceed to perform the first rotation 51. During the first rotation 51, the second rotary bar 430 rotates about a primary axis (around a major length of the second rotary bar 430) and the rotation of the second rotary bar 430 causes a rotation of the first rotary bar 420 about a primary axis of the first rotary bar 420 (around a major length of the first rotary bar 420) such that the wafer 100 is reoriented from a horizontal orientation to a vertical orientation. A second rotation 52 may then rotate the second rotary bar 430 until the wafer 100 is aligned with a wafer holder 510 affixed to the scanning arm 129. During the second rotation 52, the second rotary bar 430 rotates without rotating the first rotary bar 420.

The wafer holder 510 of the wafer scanner may be any suitable wafer holder known in the art suitable for the wafer scanner. In various embodiments, the wafer holder 510 is an electrostatic chuck (ESC). In other embodiments, the wafer holder 510 may be a vacuum chuck, or some form of clamping system configured to hold the wafer 100 during processing and scanning using the vertically mounted processing system 10.

After the second rotation 52, the wafer 100 is loaded in the wafer holder 510 of the wafer scanner. In some embodiments, the flip assembly 112 may further comprise a capacitive sensor configured to release the edge clamps 412 after sensing the wafer 100 is aligned with the wafer holder 510. As a result, the wafer 100 may be loaded in the wafer holder 510 efficiently with assurance the u-shaped wafer holder 410 of the flip assembly 112 was aligned with the wafer holder 510 of the wafer scanner. And after loading the wafer 100 in the wafer holder 510 of the wafer scanner, the flip assembly 112 may be similarly rotated from being between the processing tool of the processing chamber 110 and the wafer holder 510 of the wafer scanner. And once the flip assembly 112 is rotated out of the path of the processing beam, jet, flux of material, or stream, processing and scanning of the wafer 100 in the vertically mounted processing system 10 may commence.

In various embodiments, small translational movements may also be enabled to align the u-shaped wafer holder 410 of the flip assembly with the wafer holder 510 of the wafer scanner by using the assembly sheath 440. The assembly sheath may be coupled with bellows (such as for the shaft 230 of the flip assembly 112 embodiment in FIG. 2) to enable translations along the major length of the second rotary bar 430, or towards or away from the wafer scanner in the processing chamber 110. As a result, the wafer 100 may be more accurately aligned and vertically loaded in the wafer holder 510 of the wafer scanner using the translational movements of the assembly sheath 440.

A benefit of the vertically mounted processing system 10 further includes that processing residue produced during the processing and scanning of the wafer 100 may fall off of the wafer 100 without accumulating in features of the wafer 100. Thus, the vertical mounting of the processing system reduces material accumulation in features during processing. And an additional benefit of vertically mounting the processing system in accordance with embodiments of this disclosure is the profile of a processing module may be reduced. As a result, the processing module comprising vertically mounted processing systems (such as the vertically mounted processing system 10) occupies a smaller surface area of the cleanroom floor in a fabrication facility. Embodiment processing modules comprising vertically mounted processing systems in accordance with embodiments of this disclosure are described using FIGS. 6A-6C below.

FIGS. 6A-6C are top view schematic diagrams of processing modules comprising vertically mounted processing systems in accordance with embodiments of this disclosure. FIG. 6A illustrates a processing module 60a, FIG. 6B illustrates a processing module 60b, and FIG. 6C illustrates a processing module 60c. Similarly labeled elements may be as previously described.

FIG. 6A is a top view schematic diagram of the processing module 60a comprising three vertically mounted processing systems 10. The processing module 60a further comprises gate valves 320 coupling the processing chambers 110 of the vertically mounted processing systems 10 to the wafer transfer chamber 310, two second gate valves 610 coupling the wafer transfer chamber 310 to an element 620, and two third gate valves 630 coupling both elements 620 to an equipment front end module (EFEM) 640.

In various embodiments, the second gate valves 610 and third gate valves 630 may be the same as the gate valves 320 and may perform similar functionalities. Further, the second gate valves 610 and third gate valves 630 may be any of the conventional devices described above for the gate valves 320. In other embodiments, the second gate valves 610 may be different from the third gate valves 630 and the same as the gate valves 320. And in other embodiments, the second gate valves 610 may be the same as the third gate valves 630, but the second gate valves 610 and third gate valves 630 may be different than the gate valves 320. In various embodiments, elements 620 are load-locks that transitions the wafers from atmospheric environments to a vacuum environment.

Still referring to FIG. 6A, the EFEM 640 may be any conventional equipment front end module known in the art suitable for the processing module 60a. The top view illustrated in FIG. 6A of the processing module 60a shows the reduced physical footprint of processing modules comprising the vertically mounted processing systems 10 of this disclosure. And the benefit of having a smaller physical footprint enables processing modules, such as the processing modules 60a-60c of FIGS. 6A-6C to occupy a smaller surface area of a cleanroom floor. Another benefit may also be the smaller physical footprint enables a processing module to include more vertically mounted processing systems 10 in the same amount of space as a processing module with the conventional horizontally mounted processing systems with scanners (such as the conventional horizontally mounted PPE systems).

FIG. 6B is a top view schematic diagram of the processing module 60b comprising the vertically mounted processing system 10. The processing module 60b further comprises the gate valves 320 coupling the processing chamber 110 of the vertically mounted processing system 10 to the wafer transfer chamber 310, two second gate valves 610 coupling the wafer transfer chamber 310 to elements 620, and two third gate valves 630 coupling both elements 620 to the EFEM 640. Additionally, the processing module 60b comprises a heater 650 coupled to the wafer transfer chamber 310, and imaging modules 660 coupled to the EFEM 640. Similarly labeled elements of the processing module 60b of FIG. 6B may be as previously described for the processing module 60a of FIG. 6A, such as for the EFEM 640, elements 620, second gate valves 610, and third gate valves 630.

Still referring to FIG. 6B, the heater 650 coupled to the wafer transfer chamber 310 may be any conventional heater known in the art suitable for pre-heating the wafer 100 before transferring and processing the wafer 100 in the vertically mounted processing system 10 of this disclosure. The imaging modules 660 of the processing module 60b may be any conventional imaging module known in the art and suitable for determining various parameters of each wafer 100 in the EFEM 640 before processing. In contrast to the processing module 60a, the processing module 60b comprises a single vertically mounted processing system 10.

FIG. 6C is a top view schematic diagram of the processing module 60c comprising two vertically mounted processing systems 10 that are mirrored. The processing module 60c further comprises gate valves 320 coupling the processing chambers 110 of the vertically mounted processing systems 10 to the wafer transfer chamber 310, two second gate valves 610 coupling the wafer transfer chamber 310 to elements 620, and two third gate valves 630 coupling both elements 620 to the EFEM 640. Again, similarly labeled elements of the processing module 60c of FIG. 6C may be as previously described for the processing module 60a of FIG. 6A, such as for the EFEM 640, elements 620, second gate valves 610, and third gate valves 630.

A benefit of the vertical mounting of the processing systems of this disclosure is the embodiment processing modules 60a-60c may operate without excessive vibrations from the movement of the scanner. And further, an additional benefit of vertically mounting processing systems in accordance with embodiments of this disclosure is the enablement of processing modules comprising multiple processing systems to process multiple wafers without beats (from interference of vibrations from the multiple processing systems) impacting the efficiency and quality of the processing. In various embodiments, the embodiment processing modules 60a-60c may be examples of semiconductor processing platforms comprising multiple processing chambers for processing semiconductor wafers or semiconductor substrates. The vertically mounted processing systems of this disclosure may also improve maintenance efficiency and ergonomics for processing modules through the addition of maintenance doors on the processing chambers, such as described using FIG. 7 below.

FIG. 7 is a top view schematic diagram of a processing module 70 comprising vertically mounted processing systems 10 with maintenance doors 710 in accordance with an embodiment of this disclosure. The only difference between the processing module 70 of FIG. 7 and the processing module 60a of FIG. 6A is the maintenance doors 710 on the processing chambers 110 of the vertically mounted processing systems 10. Similarly labeled elements may be as previously described.

The maintenance doors 710 may be any suitable access door for a processing chamber known in the art. In various embodiments, the maintenance doors 710 may be stainless steel, and comprise hinges and a rubber seal to mitigate vacuum conditions within the processing chamber 110. In various embodiments, the processing tool 160 and the processing nozzle 162 may be affixed to the maintenance door 710, and opening the maintenance door 710 may enable easy access for maintenance or repair of the processing tool 160 or processing nozzle 162.

The addition of the maintenance doors 710 enable easy access for routine maintenance of the vertically mounted processing systems 10. Further, the maintenance doors 710 enable easy access for any maintenance (whether routine or not) on the flip assembly 112, or any other elements of the vertically mounted processing systems 10. Each of the maintenance doors 710 may be capable of individually or collectively opening in an access movement 720.

Although the processing module 70 of FIG. 7 is an embodiment of the processing module 60a of FIG. 6A, the addition of maintenance doors 710 is not limited to the processing module 60a of FIG. 6A. All embodiment processing modules of FIGS. 6A-6C may comprise maintenance doors in other embodiments. A method of loading a wafer in a vertically mounted processing system which may be implemented using all embodiments of the flip assembly described above and in each of the processing modules described above is described using FIG. 8 below.

FIG. 8 is a flowchart of a method of processing a wafer in a vertically mounted processing system in accordance with an embodiment of this disclosure. A method 800 of FIG. 8 may be combined with other methods and performed using the systems and apparatuses as described herein, such as the vertically mounted processing system 10 of FIGS. 1A-1B and the processing modules 60a-60c, and 70 of FIGS. 6A-6C, and FIG. 7. Although shown in a logical order, the arrangement and numbering of the steps of FIG. 8 are not intended to be limited. The method steps of FIG. 8 may be performed in any suitable order.

Referring to FIG. 8, step 810 of a method 800 of processing a wafer in a vertically mounted processing system receives a wafer on a flip assembly disposed in a processing chamber, the wafer being received in a first orientation parallel to a floor of the processing chamber, such as the flip assembly 112 of FIGS. 2 or 4. The flip assembly comprises a rotary bar coupled with a rotary drive. The wafer, the wafer holder, and the flip assembly may be the wafer 100, the wafer holder 210, and the flip assembly 112 of the vertically mounted processing system 10 of FIG. 1A in an embodiment.

Once the wafer is loaded in the wafer holder of the flip assembly, step 820 of the method 800 transfers the wafer from the flip assembly to a wafer holder disposed in the processing chamber such that the wafer is disposed along a second orientation, the second orientation being angled to the first orientation. Step 820 of the method 800 may be illustrated by the transferring 30 and lowering 31 of FIG. 3A, or by the transferring 50 of FIG. 5. In various embodiments, the first orientation may be a horizontal orientation and the second orientation may be a vertical orientation, or some other orientation angled from horizontal. After transferring the wafer from the first orientation to the second orientation in step 820, the method 800 may proceed to step 830.

Still referring to FIG. 8, step 830 of the method 800 exposes the wafer in the second orientation to a flux of material to process the wafer using a processing tool to emit the flux of material from a processing nozzle of a vertically mounted processing system. In various embodiments, the processing tool may be the processing tool 160 of FIG. 1B, the processing nozzle may be the processing nozzle 162 of FIG. 1B, and the vertically mounted processing system may be the vertically mounted processing system 10 of FIGS. 1A-1B.

In various embodiments, after the transfer in step 820, the flip assembly may be rotated to prevent impeding the flux of material and impacting the exposure in step 830. The transfer in step 820 may be illustrated using the steps described for the flip assembly 112 using FIGS. 3A-3C above.

Example embodiments of the invention are described below. Other embodiments can also be understood from the entirety of the specification as well as the claims filed herein.

Example 1. A method for processing a wafer includes receiving the wafer on a flip assembly disposed in a processing chamber, the wafer being received in a first orientation parallel to a floor of the processing chamber, the flip assembly including a rotary bar coupled to a rotary drive. The method further includes transferring the wafer from the flip assembly to a wafer holder disposed in the processing chamber such that the wafer is disposed along a second orientation in the processing chamber, the second orientation being angled to the first orientation, and exposing the wafer in the second orientation to a flux of material.

Example 2. The method of example 1, where the first orientation is orthogonal to the second orientation.

Example 3. The method of one of examples 1 or 2, where the first orientation is horizontal to the floor of the processing chamber and the second orientation is vertical to the floor of the processing chamber.

Example 4. The method of one of examples 1 to 3, where the flux of material is emitted horizontally from a processing nozzle and directed at a top surface of the wafer in the second orientation.

Example 5. The method of one of examples 1 to 4, where the flux of material includes gas clusters, ions, radicals, neutral species, or combinations thereof.

Example 6. The method of one of examples 1 to 5, where the exposing etches material on the wafer.

Example 7. The method of one of examples 1 to 6, where the exposing deposits material on the wafer.

Example 8. The method of one of examples 1 to 7, where the flux of material covers a top surface of the wafer.

Example 9. The method of one of examples 1 to 8, where the flux of material covers a portion of a top surface of the wafer.

Example 10. The method of one of examples 1 to 9, where the exposing includes emitting the flux of material from a processing nozzle, and scanning the top surface of the wafer with the flux of material by moving the processing nozzle using a scanner.

Example 11. The method of one of examples 1 to 10, where the exposing includes emitting the flux of material from a processing nozzle, and scanning the top surface of the wafer with the flux of material by moving the wafer through the flux of material using a scanner.

Example 12. The method of one of examples 1 to 11, where the exposing includes emitting the flux of material from a processing nozzle, and scanning the top surface of the wafer with the flux of material by moving both the wafer and the processing nozzle using a scanner.

Example 13. A system for processing a wafer includes a processing chamber including a processing tool, and a wafer holder oriented vertically, the processing tool including a processing nozzle. The system further includes a flip assembly disposed in the processing chamber, the flip assembly including a rotary bar, and a rotary drive, the rotary drive coupled to the rotary bar. And the system further includes a controller coupled to the wafer holder, the flip assembly, the processing chamber, the processing tool, and a memory storing instructions to be executed in the controller. The instructions when executed enable the controller to receive the wafer on the flip assembly, the wafer being received in a first orientation parallel to a floor of the processing chamber, transfer the wafer from the flip assembly to the wafer holder such that the wafer is disposed along a second orientation in the processing chamber, the second orientation being angled to the first orientation, and expose the wafer in the second orientation to a flux of material emitted from the processing nozzle of the processing tool.

Example 14. The system of example 13, where the first orientation is orthogonal to the second orientation.

Example 15. The system of one of examples 13 or 14, where the first orientation is horizontal to the floor of the processing chamber and the second orientation is vertical to the floor of the processing chamber.

Example 16. The system of one of examples 13 to 15, where the flip assembly includes a second wafer holder, and supports coupling the rotary bar to the second wafer holder, the supports offsetting the second wafer holder from the rotary bar to form an opening between the second wafer holder and the rotary bar.

Example 17. The system of one of examples 13 to 16, where the second wafer holder includes edge clamps for holding the wafer, a hole, and a pedestal configured to pass through the hole to receive and position the wafer to be clamped in the edge clamps of the second wafer holder.

Example 18. The system of one of examples 13 to 17, where the flip assembly includes a second wafer holder mechanically coupled to the rotary bar, and a second rotary bar mechanically coupled to the rotary bar through an assembly sheath such that the rotary bar is perpendicular to the second rotary bar, where the second rotary bar is mechanically coupled to the rotary bar such that rotations of the rotary bar around a first primary axis along the rotary bar cause the second rotary bar to rotate around a second primary axis of the second rotary bar and cause the second wafer holder to rotate around both the first primary axis of the rotary bar and the second primary axis of the second rotary bar.

Example 19. The system of one of examples 13 to 18, where the second wafer holder further includes edge clamps for holding the wafer, and a hole such that the second wafer holder is u-shaped.

Example 20. The system of one of examples 13 to 19, where the processing tool includes a plasma torch, and the processing chamber includes a partial plasma etch (PPE) chamber.

Example 21. The system of one of examples 13 to 20, where the processing tool includes a gas cluster tool, and the processing chamber includes a gas cluster chamber.

Example 22. The system of one of examples 13 to 21, where the flux of material includes gas clusters, ions, radicals, neutral species, or combinations thereof.

Example 23. The system of one of examples 13 to 22, where the processing tool etches material on the wafer.

Example 24. The system of one of examples 13 to 23, where the processing tool deposits material on the wafer.

Example 25. The system of one of examples 13 to 24, further including a scanner disposed in a scanning chamber coupled to the processing chamber, the scanner including a scanning arm that reaches from the scanning chamber into the processing chamber to hold the wafer.

Example 26. The system of one of examples 13 to 25, where the scanning arm is coupled to the wafer holder, and where the scanner is configured to move the wafer through the flux of material to expose portions of a top surface of the wafer to the flux of material as desired.

Example 27. The system of one of examples 13 to 26, where the scanning arm is coupled to the processing tool, and where the scanner is configured to move the processing tool to expose portions of a top surface of the wafer to the flux of material as desired.

Example 28. A semiconductor processing platform includes one or more processing chambers configured to process one or more wafers oriented vertically using a flux of material emitted horizontally, and a wafer transfer chamber coupled to the one or more processing chambers. The wafer transfer chamber being configured to translate under vacuum one or more wafers oriented horizontally, rotate the one or more wafers oriented horizontally to be vertically oriented using a flip assembly, and load the one or more wafers oriented vertically into the one or more processing chambers for processing with the flux of material.

Example 29. The semiconductor processing platform of example 28, where the flux of material includes gas clusters, ions, radicals, neutral species, or combinations thereof.

Example 30. The semiconductor processing platform of one of examples 28 or 29, where the flux of material etches material on the one or more wafers oriented vertically.

Example 31. The semiconductor processing platform of one of examples 28 to 30, where the flux of material deposits material on the one or more wafers oriented vertically.

Example 32. The semiconductor processing platform of one of examples 28 to 31, where the flip assembly includes a rotary bar, and a rotary drive coupled to the rotary bar.

While the inventive aspects are described primarily in the context of burnishing modules for semiconductor processing equipment, it should also be appreciated that these inventive aspects may also apply to other types of precision manufacturing equipment that involve scanning operations. In particular, aspects of this disclosure may similarly apply to inspection systems, laser processing equipment, precision deposition systems, and other manufacturing tools where vibration control and space utilization are important considerations.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. For example, embodiments may comprise combinations of embodiments discussed in FIGS. 1-8. It is therefore intended that the appended claims encompass any such modifications or embodiments.

What is claimed is:

1. A method for processing a wafer, the method comprising:
receiving the wafer on a flip assembly disposed in a processing chamber, the wafer being received in a first orientation parallel to a floor of the processing chamber, the flip assembly comprising a rotary bar coupled to a rotary drive; transferring the wafer from the flip assembly to a wafer holder disposed in the processing chamber such that the wafer is disposed along a second orientation in the processing chamber, the second orientation being angled to the first orientation; and exposing the wafer in the second orientation to a flux of material.

2. The method of claim 1, wherein the flux of material comprises gas clusters, ions, radicals, neutral species, or combinations thereof, and wherein the first orientation is orthogonal to the second orientation.

3. The method of claim 1, wherein the flux of material comprises gas clusters, ions, radicals, neutral species, or combinations thereof, and wherein the first orientation is horizontal to the floor of the processing chamber and the second orientation is vertical to the floor of the processing chamber.

4. The method of claim 1, wherein the exposing etches material on the wafer.

5. The method of claim 1, wherein the exposing deposits material on the wafer.

6. The method of claim 1, wherein the exposing comprises:
emitting the flux of material from a processing nozzle; and scanning a top surface of the wafer with the flux of material by moving the processing nozzle using a scanner.

7. The method of claim 1, wherein the exposing comprises:
emitting the flux of material from a processing nozzle; and scanning a top surface of the wafer with the flux of material by moving the wafer through the flux of material using a scanner.

8. The method of claim 1, wherein the exposing comprises:
emitting the flux of material from a processing nozzle; and scanning a top surface of the wafer with the flux of material by moving both the wafer and the processing nozzle using a scanner.

9. A system for processing a wafer, the system comprising:
a processing chamber comprising a processing tool, and a wafer holder oriented vertically, the processing tool comprising a processing nozzle; a flip assembly disposed in the processing chamber, the flip assembly comprising a rotary bar, and a rotary drive, the rotary drive coupled to the rotary bar; and
a controller coupled to the wafer holder, the flip assembly, the processing chamber, the processing tool, and a memory storing instructions to be executed in the controller, the instructions when executed enable the controller to:
receive the wafer on the flip assembly, the wafer being received in a first orientation parallel to a floor of the processing chamber, transfer the wafer from the flip assembly to the wafer holder such that the wafer is disposed along a second orientation in the processing chamber, the second orientation being angled to the first orientation, and expose the wafer in the second orientation to a flux of material emitted from the processing nozzle of the processing tool.

10. The system of claim 9, wherein the flux of material comprises gas clusters, ions, radicals, neutral species, or combinations thereof, and wherein the first orientation is orthogonal to the second orientation.

11. The system of claim 9, wherein the flux of material comprises gas clusters, ions, radicals, neutral species, or combinations thereof, and wherein the first orientation is horizontal to the floor of the processing chamber and the second orientation is vertical to the floor of the processing chamber.

12. The system of claim 9, wherein the flip assembly comprises:
a second wafer holder comprising edge clamps for holding the wafer, a hole, and a pedestal configured to pass through the hole to receive and position the wafer to be clamped in the edge clamps of the second wafer holder; and supports coupling the rotary bar to the second wafer holder, the supports offsetting the second wafer holder from the rotary bar to form an opening between the second wafer holder and the rotary bar.

13. The system of claim 9, wherein the flip assembly comprises:
a second wafer holder mechanically coupled to the rotary bar, the second wafer holder comprising edge clamps for holding the wafer, and a hole such that the second wafer holder is u-shaped; and a second rotary bar mechanically coupled to the rotary bar through an assembly sheath such that the rotary bar is perpendicular to the second rotary bar, wherein the second rotary bar is mechanically coupled to the rotary bar such that rotations of the rotary bar around a first primary axis along the rotary bar cause the second rotary bar to rotate around a second primary axis of the second rotary bar and cause the second wafer holder to rotate around both the first primary axis of the rotary bar and the second primary axis of the second rotary bar.

14. The system of claim 9, wherein the processing tool comprises a gas cluster tool, and the processing chamber comprises a gas cluster chamber.

15. The system of claim 9, further comprising a scanner disposed in a scanning chamber coupled to the processing chamber, the scanner comprising a scanning arm that reaches from the scanning chamber into the processing chamber to hold the wafer, wherein the scanning arm is coupled to the wafer holder, and wherein the scanner is configured to move the wafer through the flux of material to expose portions of a top surface of the wafer to the flux of material as desired.

16. The system of claim 9, further comprising a scanner disposed in a scanning chamber coupled to the processing chamber, the scanner comprising a scanning arm that reaches from the scanning chamber into the processing chamber to hold the wafer, wherein the scanning arm is coupled to the processing tool, and wherein the scanner is configured to move the processing tool to expose portions of a top surface of the wafer to the flux of material as desired.

17. A semiconductor processing platform comprising:
one or more processing chambers configured to process one or more wafers oriented vertically using a flux of material emitted horizontally; and
a wafer transfer chamber coupled to the one or more processing chambers, the wafer transfer chamber being configured to:
translate under vacuum one or more wafers oriented horizontally, rotate the one or more wafers oriented horizontally to be vertically oriented using a flip assembly, and load the one or more wafers oriented vertically into the one or more processing chambers for processing with the flux of material.

18. The semiconductor processing platform of claim 17, wherein the flip assembly comprises a rotary bar, and a rotary drive coupled to the rotary bar, and wherein the flux of material comprises gas clusters, ions, radicals, neutral species, or combinations thereof.

19. The semiconductor processing platform of claim 17, wherein the flux of material etches material on the one or more wafers oriented vertically.

20. The semiconductor processing platform of claim 17, wherein the flux of material deposits material on the one or more wafers oriented vertically.
